(19) United States
(12) Patent Application Publication
(10) Pub. No.: US 2026/0002960 A1
(43) Pub. Date: Jan. 1, 2026

(54) ELECTRICAL COMPONENT SOCKET

(71) Applicant: Enplas Corporation, Kawaguchi-shi (JP)

(72) Inventor: Yoshinobu HAGIWARA, Kawaguchi-shi (JP)

(73) Assignee: Enplas Corporation, Kawaguchi-shi (JP)

(21) Appl. No.: 19/248,616

(22) Filed: Jun. 25, 2025

(30) Foreign Application Priority Data
Jun. 28, 2024 (JP) 2024-105645

(51) Int. Cl. G01R 1/04; G01R 31/28; H01R 13/18; H01R 13/629; H01R 33/76

(52) U.S. Cl. CPC G01R 1/0466; G01R 31/2886; H01R 13/18; H01R 13/62977; H01R 33/7664

(57) ABSTRACT

Provided is an electrical component socket including: a movable support member that is provided on a side of one end of a main body so as to be movable in an up-down direction; a cover member of which a side of a base end is pivotably coupled to a support portion of the movable support member; a lever member of which a side of a base end is pivotably coupled to the side of the one end of the main body; and a link member of which a side of a base end is pivotably coupled to a side of another end of the main body. The cover member is locked to a locked portion of the link member by a closing operation of the cover member. The locked portion and the support portion push down the cover member by a closing operation of the lever member.

### CROSS REFERENCE TO RELATED APPLICATIONS

This application is entitled to or claims the benefit of Japanese Patent Application No. 2024-105645, filed on Jun. 28, 2024, the disclosure of which including the specification, drawings and abstract is incorporated herein by reference in its entirety.

### TECHNICAL FIELD

The present invention relates to an electrical component socket.

### BACKGROUND ART

In the related art, for example, an electrical component socket as illustrated in Patent Literature (hereinafter referred to as “PTL”) 1 has been used when an electrical test of an electrical component is conducted. The above electrical component socket according to the related art includes a socket main body that accommodates an electrical component. The side of the base end of a cover member that presses the electrical component accommodated in the socket main body is pivotably coupled to a side of one end of the socket main body. The cover member pivots in an opening and closing direction about a pivot shaft.

### CITATION LIST

### Patent Literature

### PTL 1

U.S. Patent Application Publication No. 2003/0060073

### SUMMARY OF INVENTION

### Technical Problem

Incidentally, in the electrical component socket according to the related art, the cover member pivots in a closing direction about the pivot shaft to press the electrical component accommodated in the socket main body, and thus, a force in an oblique downward direction may act on the electrical component from the cover member. In this case, there are such problems that when an electrical test of the electrical component is conducted, the electrical component is laterally displaced on the socket main body and a terminal of the electrical component is damaged or the cover member rubs against an upper surface of the electrical component to cause a scratch on the upper surface of the electrical component.

Given the above, an object of the present invention is to provide an electrical component socket capable of suppressing damage to a terminal of an electrical component and the occurrence of a scratch on an upper surface of the electrical component when an electrical test of the electrical component is conducted.

### Solution to Problem

An aspect of an electrical component socket according to the present invention includes:
a socket main body that accommodates an electrical component;
a movable support member that is provided on a side of one end of the socket main body so as to be movable in an up-down direction and includes a support portion;
a cover member of which a side of a base end is pivotably coupled to the support portion and which presses the electrical component accommodated in the socket main body;
a lever member of which a side of a base end is pivotably coupled to the side of the one end of the socket main body;
a link member of which a side of a base end is pivotably coupled to a side of another end of the socket main body and which includes a locked portion;
a first interlocking mechanism that presses a side of a leading end of the link member in a downward direction in conjunction with a pivoting operation of the lever member in a closing direction; and
a second interlocking mechanism that moves the movable support member in the downward direction in conjunction with the pivoting operation of the lever member in the closing direction, wherein
a part of the cover member is locked to the locked portion by a pivoting operation of the cover member in the closing direction, and
the locked portion and the support portion push down the cover member by interlocking the first interlocking mechanism with the second interlocking mechanism by the pivoting operation of the lever member in the closing direction.

### Advantageous Effects of Invention

According to the present invention, it is possible to suppress damage to a terminal of an electrical component and the occurrence of a scratch on an upper surface of the electrical component when an electrical test of the electrical component is conducted.

### BRIEF DESCRIPTION OF DRAWINGS

FIG. 1 is a perspective view of an electrical component socket, illustrating a state in which a cover member is opened, according to the present embodiment;

FIG. 2 is a perspective view of the electrical component socket, in which a lever member is omitted from the state illustrated in FIG. 1, according to the present embodiment;

FIG. 3 is a perspective view of the electrical component socket, in which a cover member main body and the lever member are omitted from the state illustrated in FIG. 1, according to the present embodiment;

FIG. 4 is a perspective view of the electrical component socket, illustrating a state in which the cover member is closed, according to the present embodiment;

FIG. 5 is a perspective view of the electrical component socket, in which the lever member is omitted from the state illustrated in FIG. 4, according to the present embodiment;

FIG. 6 is a perspective view of the electrical component socket, in which the cover member main body and the lever member are omitted from the state illustrated in FIG. 4, according to the present embodiment;

FIG. 7 is an enlarged perspective view of the periphery of a cam mechanism and a pressing mechanism, from which the cover member main body and the lever member are omitted, and FIG. 7 illustrates a state in which the cover member is opened;

FIG. 8 is an enlarged perspective view of the periphery of the cam mechanism and the pressing mechanism, from which the cover member main body and the lever member are omitted, and FIG. 8 illustrates a state in which the cover member is closed;

FIG. 9A is a diagram describing how a latch pin is locked to a locked portion of a link member by a pivoting operation of the cover member in a closing direction;

FIG. 9B is a diagram describing how the latch pin is locked to the locked portion of the link member by the pivoting operation of the cover member in the closing direction;

FIG. 9C is a diagram describing how the latch pin is locked to the locked portion of the link member by the pivoting operation of the cover member in the closing direction;

FIG. 9D is a diagram describing how the latch pin is locked to the locked portion of the link member by the pivoting operation of the cover member in the closing direction;

FIG. 9E is a diagram describing how the latch pin is locked to the locked portion of the link member by the pivoting operation of the cover member in the closing direction;

FIG. 9F is a diagram describing how the locked portion of the link member pushes down the cover member by a pivoting operation of the lever member in the closing direction;

FIG. 9G is a diagram describing how the locked portion of the link member pushes down the cover member by the pivoting operation of the lever member in the closing direction;

FIG. 9H is a diagram describing how the locked portion of the link member pushes down the cover member by the pivoting operation of the lever member in the closing direction;

FIG. 10A is a diagram describing how a support portion of a movable support member pushes down the cover member by the pivoting operation of the lever member in the closing direction;

FIG. 10B is a diagram describing how the support portion of the movable support member pushes down the cover member by the pivoting operation of the lever member in the closing direction;

FIG. 10C is a diagram describing how the support portion of the movable support member pushes down the cover member by the pivoting operation of the lever member in the closing direction;

FIG. 10D is a diagram describing how the support portion of the movable support member pushes down the cover member by the pivoting operation of the lever member in the closing direction; and

FIG. 10E is a diagram describing how the support portion of the movable support member pushes down the cover member by the pivoting operation of the lever member in the closing direction.

### DESCRIPTION OF EMBODIMENTS

Hereinafter, the present embodiment will be described with reference to the accompanying drawings. In the specification and claims, the opening and closing direction of the cover member or the like refers to the up-down direction in which the cover member or the like is opened and closed. The opening direction of the cover member or the like refers to the upward direction in which the cover member or the like is opened, and the closing direction of the cover member or the like refers to the downward direction in which the cover member or the like is closed. Note that, in the drawings, “LD” indicates the left direction, “RD” indicates the right direction, “FD” indicates the front direction, “BD” indicates the back direction, “UD” indicates the upward direction, and “DD” indicates the downward direction.

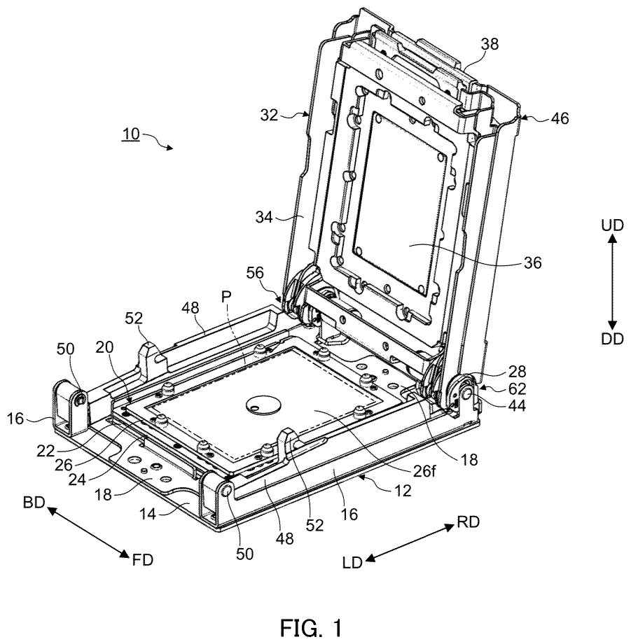

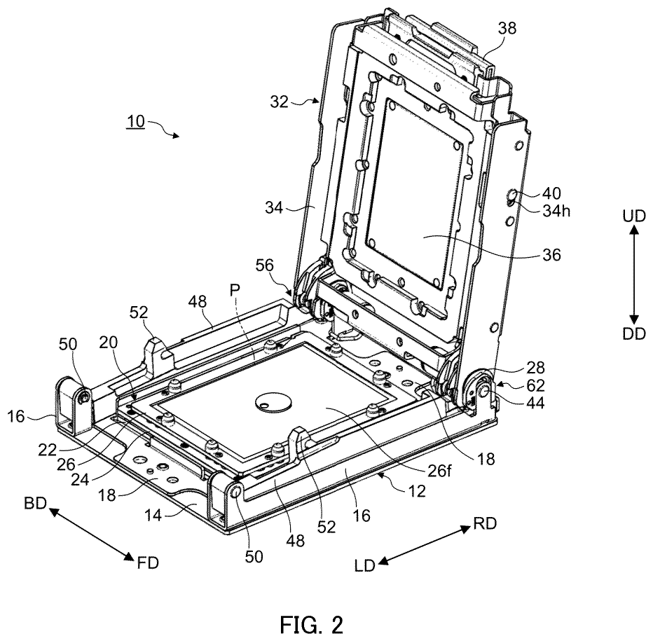

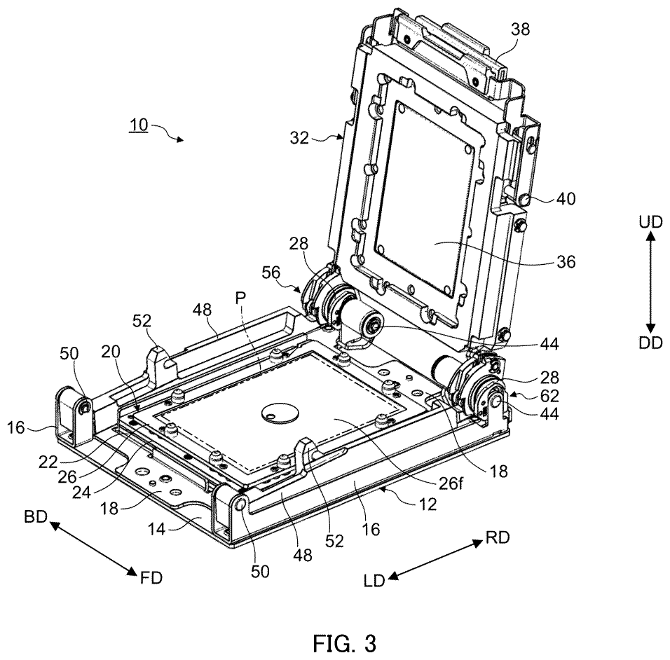

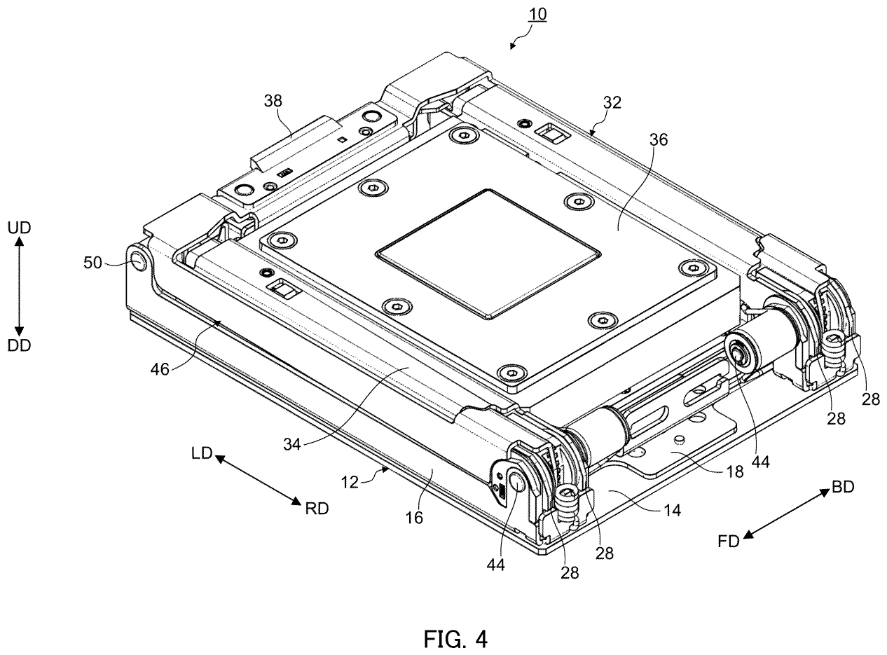

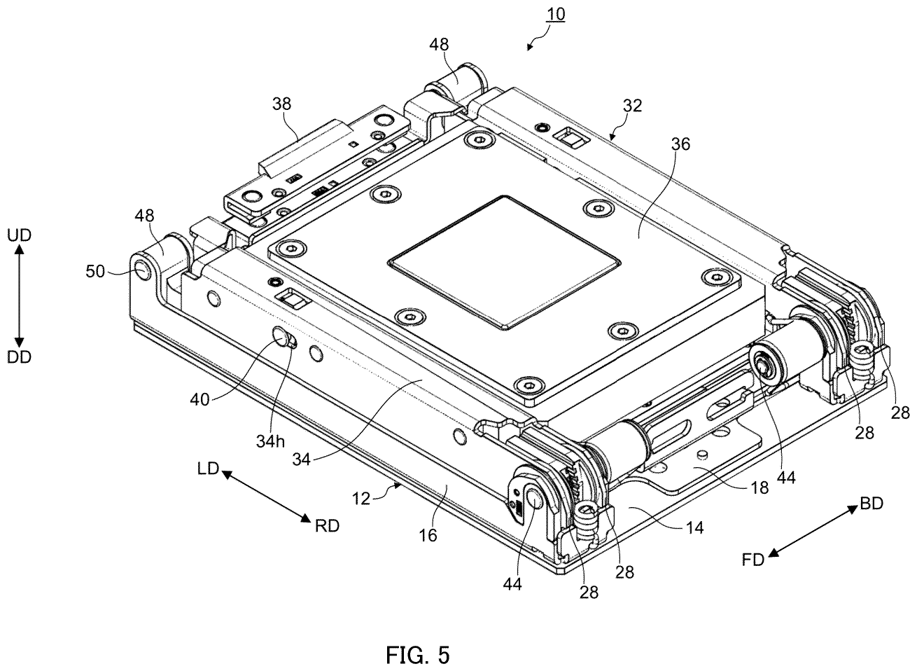

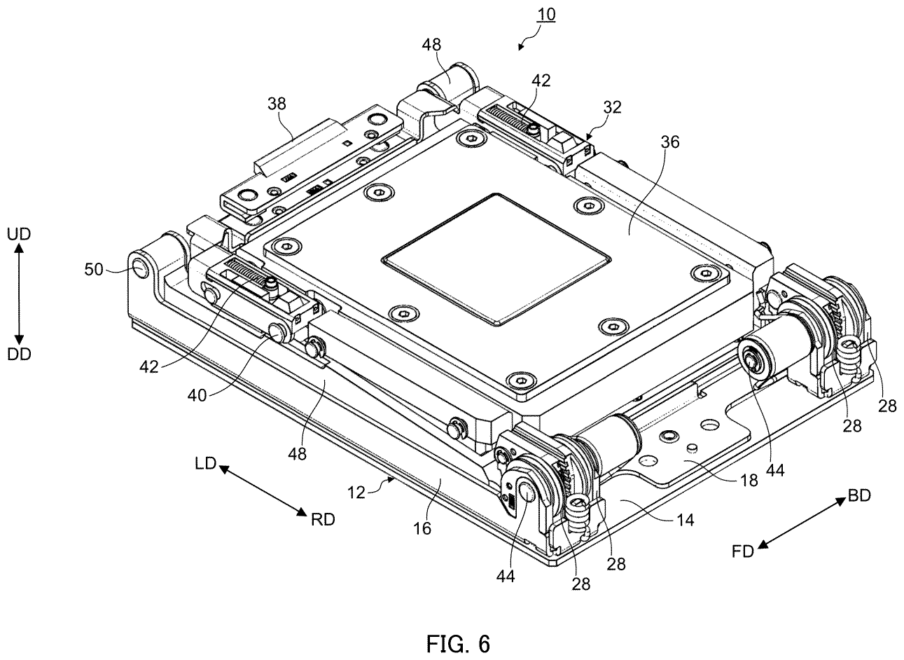

A specific configuration of electrical component socket 10 according to the present embodiment will be described with reference to FIGS. 1 to 10E. FIGS. 1 to 3 are perspective views of electrical component socket 10, illustrating a state in which cover member 32 is opened, according to the present embodiment. In FIG. 2, lever member 46 is omitted from the state illustrated in FIG. 1. In FIG. 3, cover member main body 34 and lever member 46 are omitted from the state illustrated in FIG. 1. FIGS. 4 to 6 are perspective views of electrical component socket 10, illustrating a state in which cover member 32 is closed, according to the present embodiment. In FIG. 5, lever member 46 is omitted from the state illustrated in FIG. 4. In FIG. 6, cover member main body 34 and lever member 46 are omitted from the state illustrated in FIG. 4.

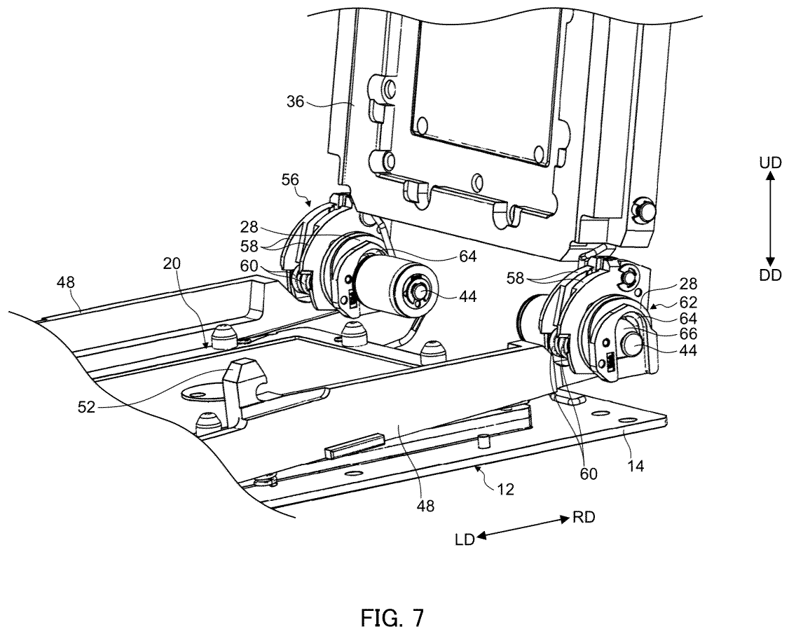

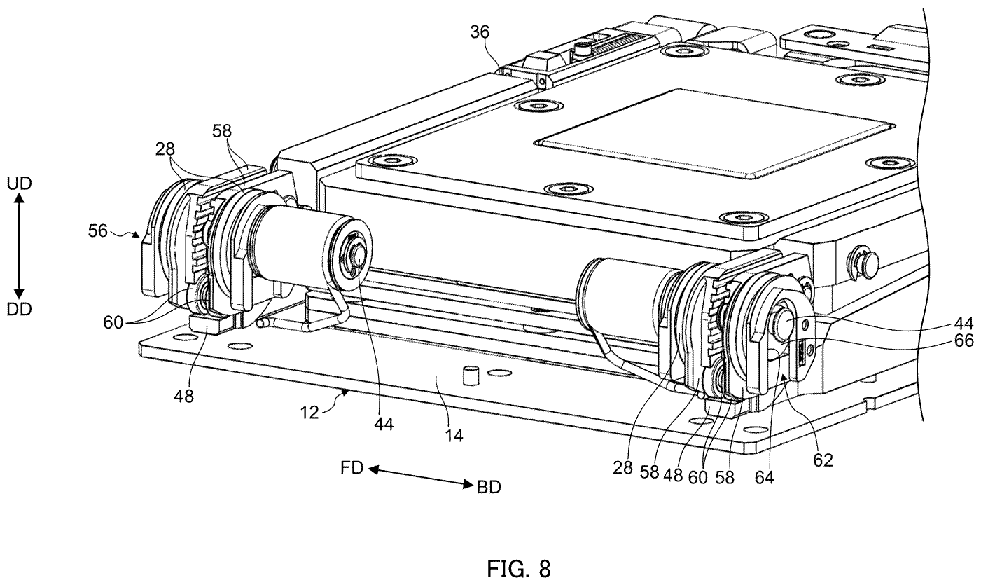

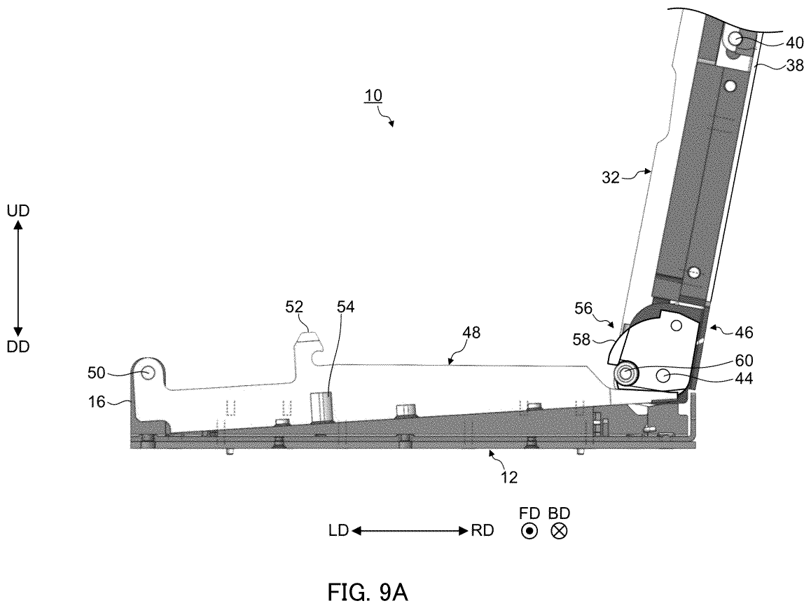

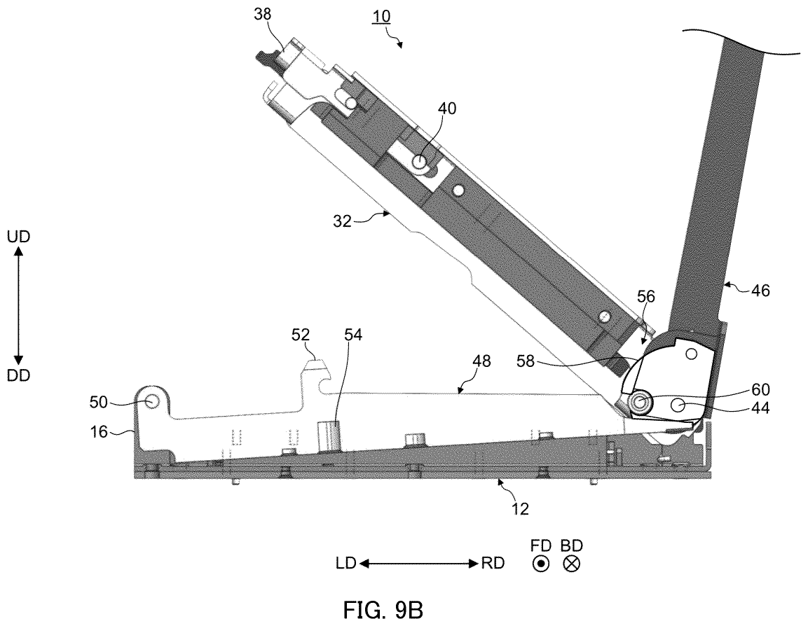

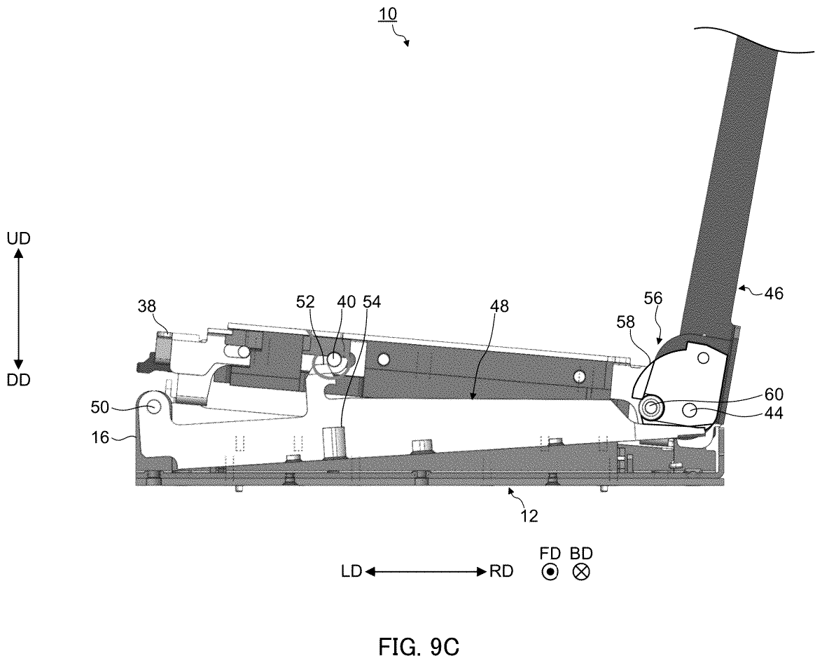

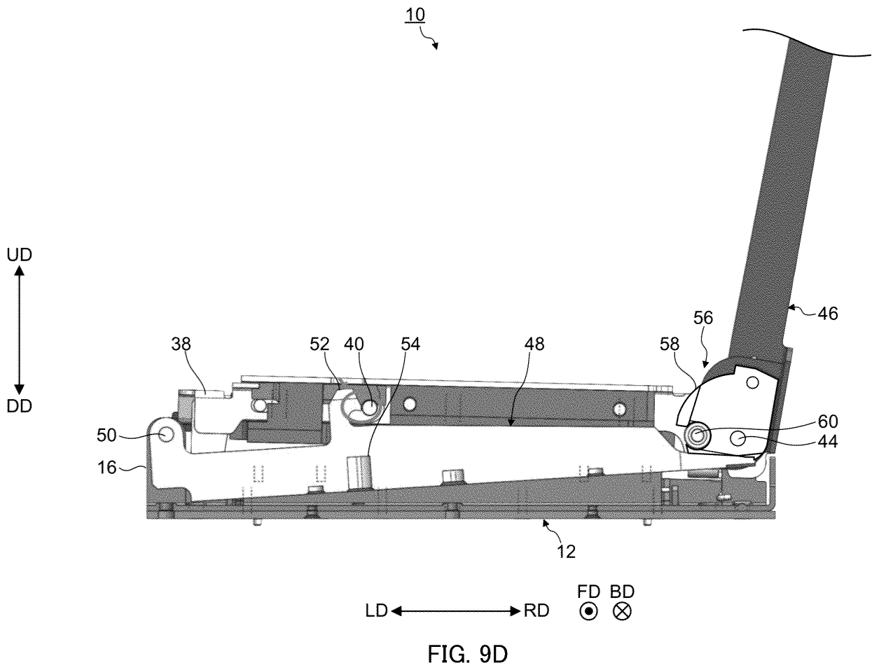

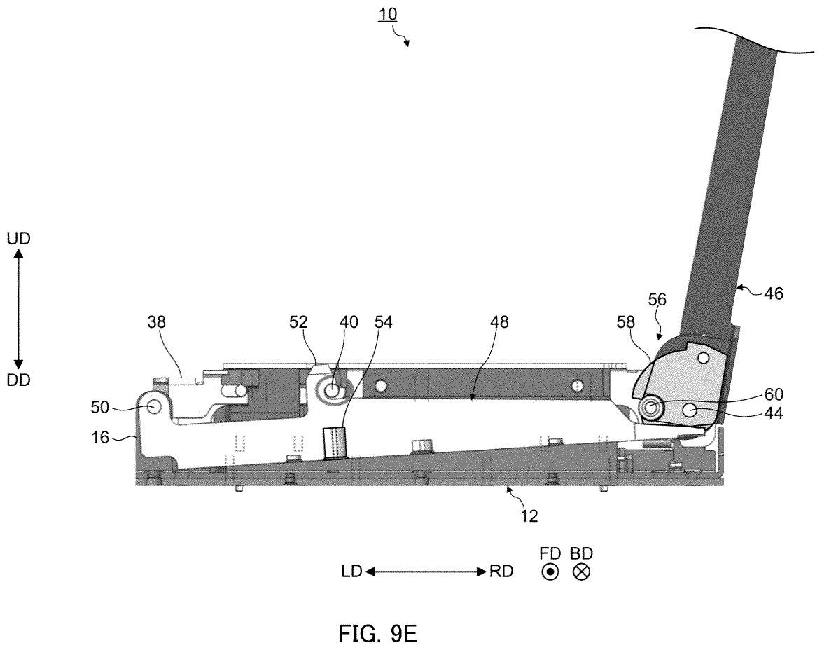

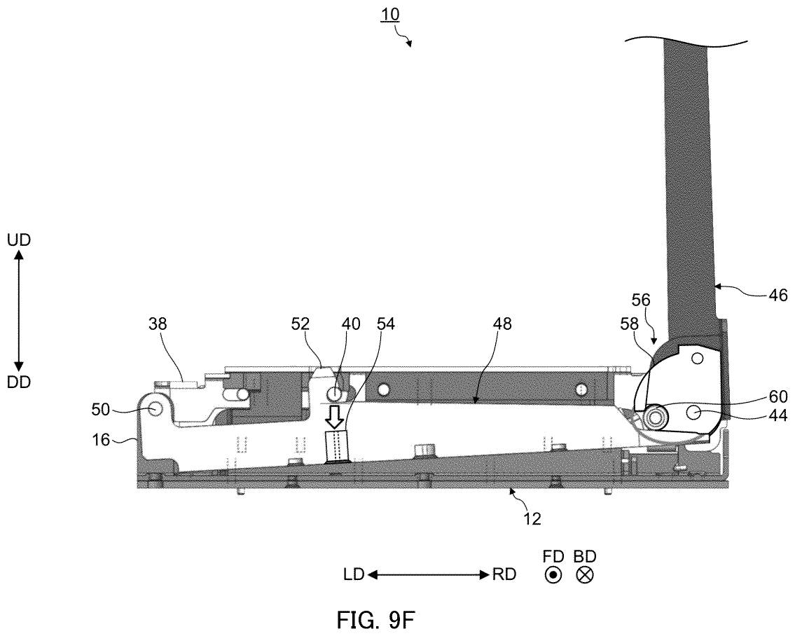

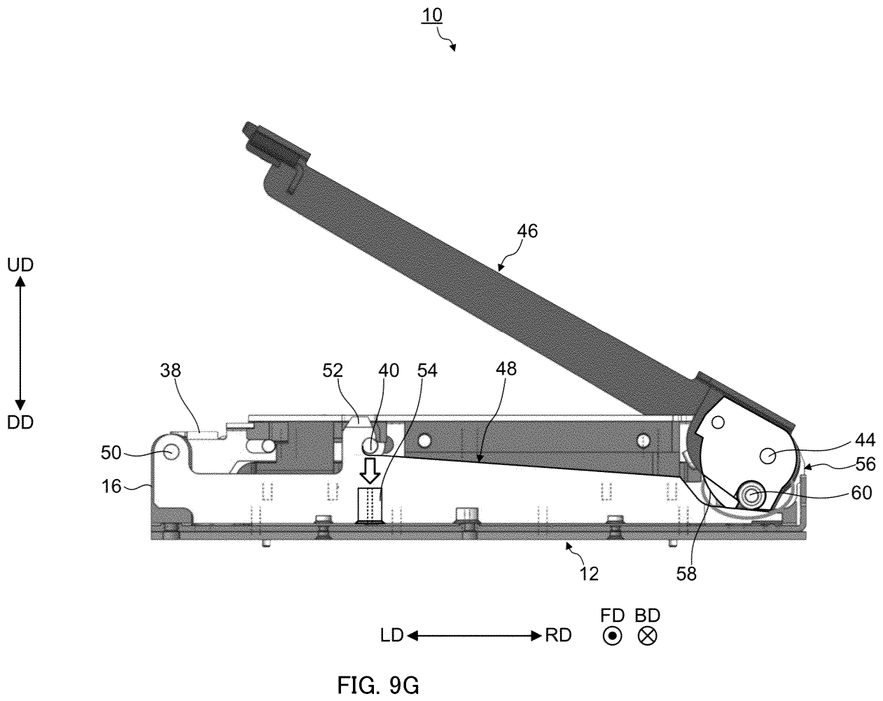

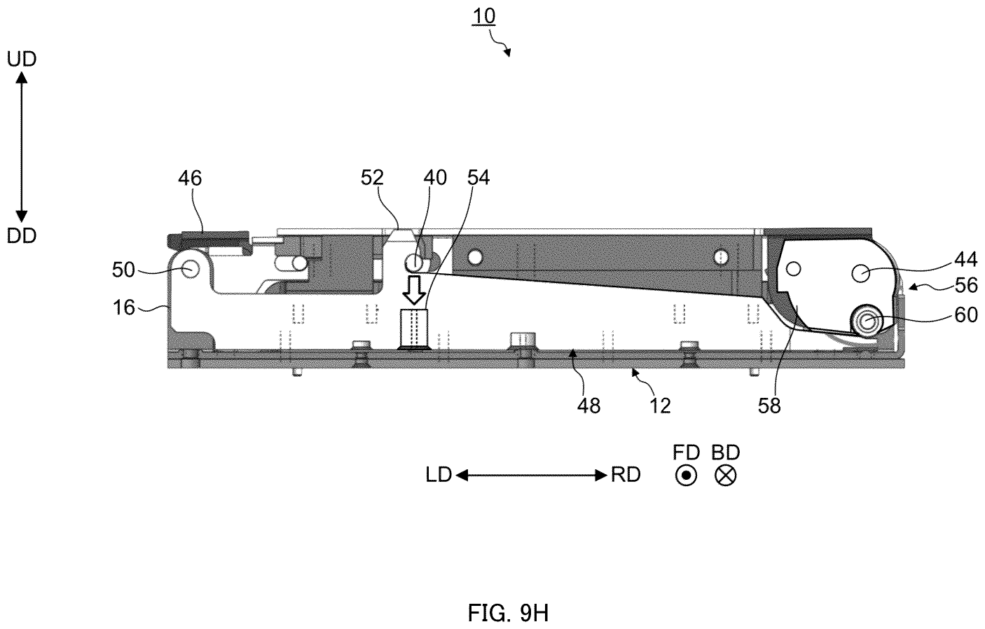

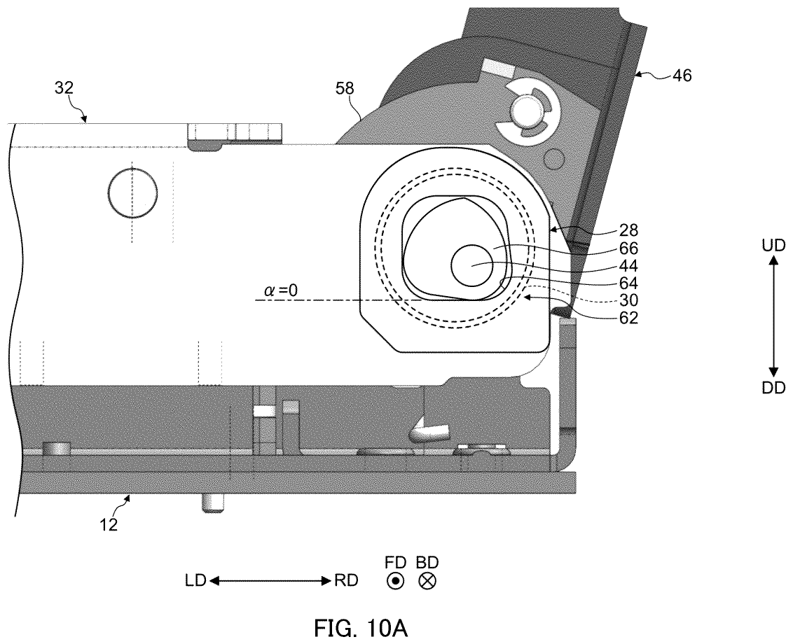

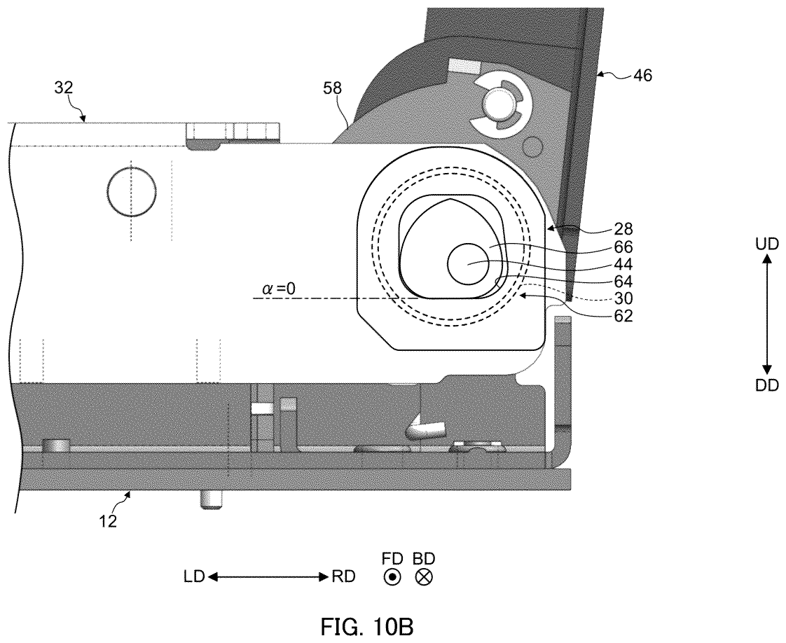

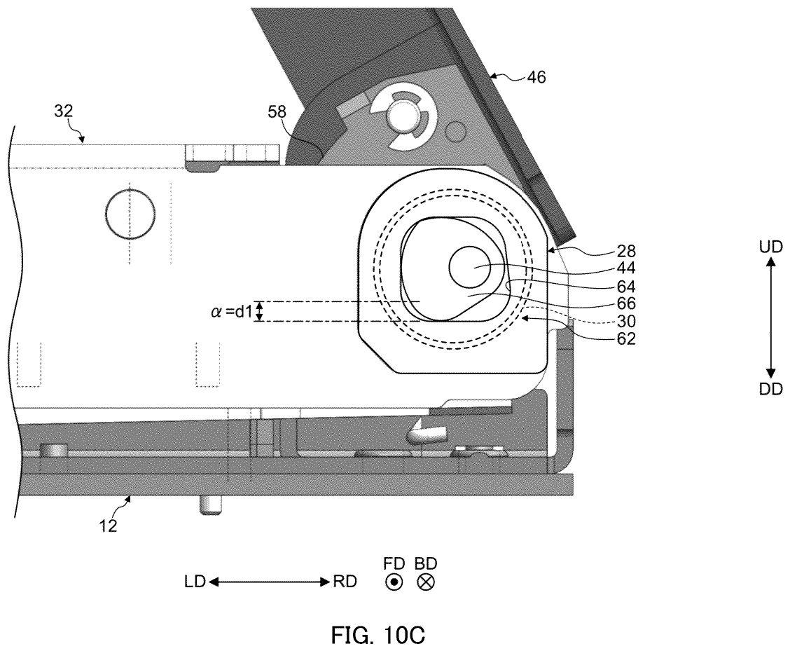

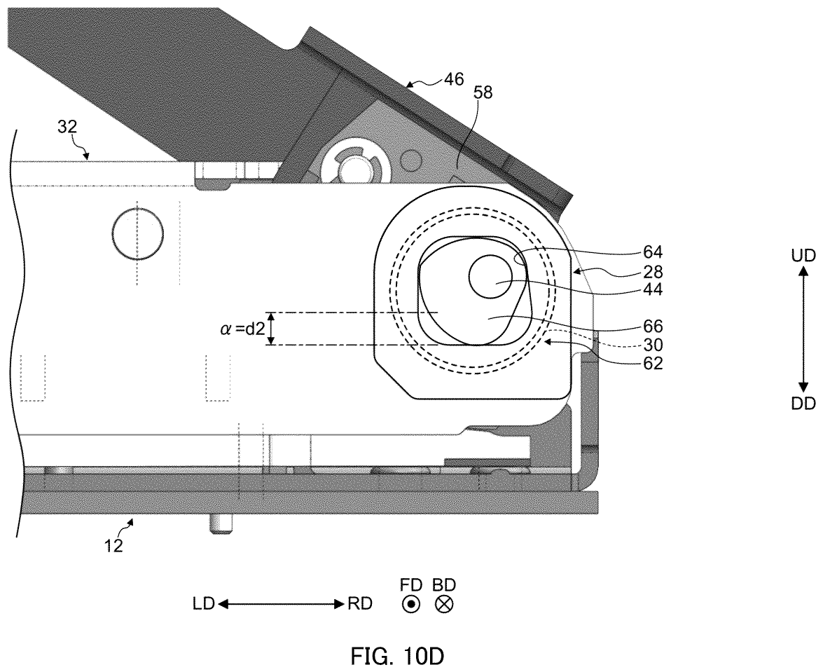

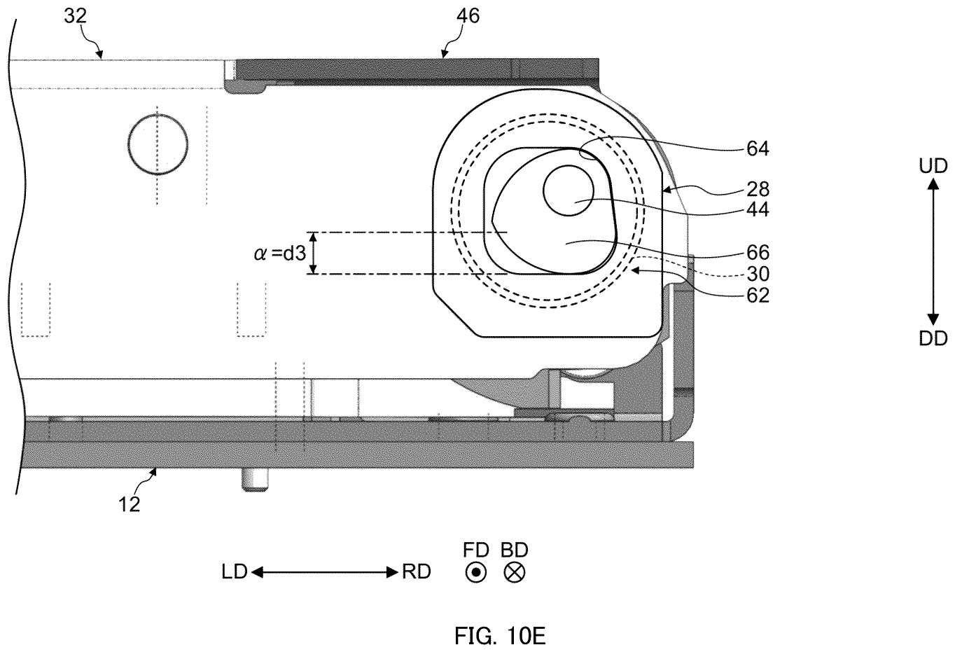

FIGS. 7 and 8 are enlarged perspective views of the periphery of cam mechanism 62 and pressing mechanism 56, from which cover member main body 34 and lever member 46 are omitted. FIG. 7 illustrates a state in which cover member 32 is opened, and FIG. 8 illustrates a state in which cover member 32 is closed. FIGS. 9A to 9E are diagrams describing how latch pin 40 is locked to locked portion 52 of link member 48 by a pivoting operation of cover member 32 in a closing direction. FIGS. 9F to 9H are diagrams describing how locked portion 52 of link member 48 pushes down cover member 32 by a pivoting operation of lever member 46 in the closing direction. FIGS. 10A to 10E are diagrams describing how support portion 30 of movable support member 28 pushes down cover member 32 by the pivoting operation of lever member 46 in the closing direction.

As illustrated in FIGS. 1 to 6, electrical component socket 10 according to the present embodiment is, for example, an apparatus used for an electrical test such as a bar-in test of electrical component P such as an integrated circuit (IC) package. Electrical component socket 10 is disposed in a test wiring board (not illustrated) connected to a test apparatus (not illustrated). Electrical component socket 10 electrically connects each terminal (not illustrated) of electrical component P to each electrode (not illustrated) of the test wiring board.

Electrical component socket 10 includes socket main body 12 that has a rectangular shape in a plan view and accommodates electrical component P. Socket main body 12 includes base plate 14, which has a rectangular shape and is disposed in the test wiring board, and a pair of fixed frames 16 provided in an upper surface of base plate 14 to be apart from each other in the front-back direction and extending in the left-right direction. The pair of fixed frames 16 is disposed on the sides of the both ends of the upper surface of base plate 14 in the front-back direction. The sides of the both ends of the pair of fixed frames 16 in the left-right direction may be coupled to each other by coupling frame 18.

As illustrated in FIGS. 1 to 3, socket main body 12 includes contact pin unit 20 provided in a central portion of the upper surface of base plate 14. Contact pin unit 20 has, for example, a configuration known in the art indicated in Japanese Patent Application Laid-Open No. 2017-37722. Contact pin unit 20 includes lower plate 22, which is provided in the central portion of the upper surface of base plate 14, and upper plate 24, which is provided on an upper side of lower plate 22. Contact pin unit 20 includes floating plate 26 provided, on an upper side of upper plate 24, in a state of being biased in the upward direction. Floating plate 26 corresponds to an accommodation portion that accommodates electrical component P. In other words, socket main body 12 includes floating plate 26 as the accommodation portion that accommodates electrical component P. Floating plate 26 includes placement surface 26f on which electrical component P is placed, and placement surface 26f has a horizontal plane.

Contact pin unit 20 includes a plurality of contact pins (not illustrated) that electrically connects the terminals (not illustrated) of electrical component P to the electrodes (not illustrated) of the test wiring board. The plurality of contact pins is disposed in a matrix shape, and each contact pin is held in a state of being inserted through through-holes (not illustrated) that are formed in lower plate 22, upper plate 24, and floating plate 26, respectively. The upper end of each contact pin can come into contact with a terminal of electrical component P, and the lower end of each contact pin is in contact with an electrode of the test wiring board. Each contact pin is biased in the upward direction by a spring (not illustrated) as a pin biasing portion.

As illustrated in FIGS. 1 to 8, a pair of movable support members 28 is provided on a side of one end of each fixed frame 16 in the left-right direction so as to be movable in the up-down direction. In other words, two pairs of movable support members 28 are provided on a side of one end of socket main body 12 in the left-right direction so as to be movable in the up-down direction, and the two pairs of movable support members 28 are apart from each other in the front-back direction. Each movable support member 28 includes support portion 30 having an annular (cylindrical) shape (see FIG. 10A).

The side of the base end of cover member 32 that presses electrical component P accommodated in floating plate 26 is coupled to support portions 30 of the two pairs of movable support members 28 so as to be pivotable in the opening and closing direction. Cover member 32 pivots in the opening and closing direction about the pivot axis center of cover member 32 on the side of the base end of cover member 32. Cover member 32 is configured to switch between an erected posture and a horizontally fallen posture by a pivoting operation of cover member 32 in the opening and closing direction. The pivot axis center of cover member 32 coincides with the centers of support portions 30 of the two pairs of movable support members 28 and is displaced in the up-down direction by the movement of the two pairs of movable support members 28 in the up-down direction. In addition, cover member 32 is biased in the opening direction by a cover biasing portion such as a spring.

As illustrated in FIGS. 1, 2, 4, and 5, cover member 32 includes cover member main body 34 having a rectangular frame shape, and the side of the base end of cover member main body 34 is coupled to support portions 30 (see FIG. 10A) of the two pairs of movable support members 28 so as to be pivotable in the opening and closing direction. Long hole 34h extending in the longitudinal direction of cover member 32 is formed on the side closer to the leading end of cover member main body 34. In addition, cover member 32 includes pressing member 36 that is disposed on the inner side of cover member main body 34 and presses electrical component P. Pressing member 36 is configured to be pivotable with respect to cover member main body 34 and displaceable in the up-down direction.

As illustrated in FIGS. 4 to 6 and 9B, latch member 38 having an inverted U shape is provided on the side of the leading end of cover member main body 34 so as to be movable in the longitudinal direction of cover member main body 34, and latch member 38 is configured to be non-detachable from cover member main body 34. Latch member 38 includes a pair of latch pins 40, and the pair of latch pins 40 is apart from each other in the front-back direction. Each latch pin 40 is engaged with long hole 34h of cover member main body 34 so as to be movable in the longitudinal direction of cover member main body 34. In addition, at appropriate positions of cover member main body 34, a plurality of springs 42 (see FIG. 6) is provided as a latch biasing portion that biases latch member 38 in the direction of the leading end of cover member main body 34.

As illustrated in FIGS. 1 to 8, pivot shaft (hinge shaft) 44 is pivotably provided on the side of the one end of each fixed frame 16 in the left-right direction. In other words, a pair of pivot shafts 44 is pivotably provided on the side of the one end of socket main body 12 in the left-right direction, and the pair of pivot shafts 44 is apart from each other in the front-back direction. Each pivot shaft 44 is inserted through the insides of support portions 30 (see FIG. 10A) of the pair of movable support members 28.

As illustrated in FIGS. 1 to 6, the side of the base end of lever member 46 having an inverted U shape for pressing cover member 32 is integrally coupled to the pair of pivot shafts 44. In other words, the side of the base end of lever member 46 is provided on the side of the one end of socket main body 12 in the left-right direction so as to be pivotable in the opening and closing direction via the pair of pivot shafts 44. Lever member 46 pivots in the opening and closing direction about the pivot axis center of lever member 46 on the side of the base end of lever member 46. The pivot axis center of lever member 46 coincides with the shaft center of pivot shaft 44 and is deviated from the pivot axis center of cover member 32. Lever member 46 is configured to switch between an erected posture and a fallen posture by a pivoting operation of lever member 46 in the opening and closing direction.

As illustrated in FIGS. 1 to 3 and 9A, the side of the base end of link member 48 is coupled to the side of the other end of each fixed frame 16 in the left-right direction so as to be pivotable in the opening and closing direction via pivot pin (hinge pin) 50. In other words, the sides of the base ends of the pair of link members 48 are coupled to the side of the other end of socket main body 12 in the left-right direction so as to be pivotable in the opening and closing direction via pivot pins 50. The pair of link members 48 is apart from each other in the front-back direction, and each link member 48 extends in the left-right direction.

Each link member 48 includes locked portion 52 having a hook shape, and each locked portion 52 is located at a position closer to the base end of each link member 48 than to the leading end of each link member 48. Further, at appropriate positions of socket main body 12, springs 54 (see FIG. 9A) are provided as a link biasing portion that biases each link member 48 in the opening direction.

As illustrated in FIGS. 6 and 9A to 9E, each latch pin 40 as a part of cover member 32 climbs over each locked portion 52 against the biasing force of spring 54 by the pivoting operation of cover member 32 in the closing direction. Then, after each latch pin 40 climbs over each locked portion 52 by the pivoting operation of cover member 32 in the closing direction, each latch pin 40 is locked to each locked portion 52 by the biasing force of spring 54.

As illustrated in FIGS. 7, 8, and 9A to 9H, electrical component socket 10 includes pressing mechanism 56 as a first interlocking mechanism that presses the sides of the leading ends of the pair of link members 48 in the downward direction in conjunction with the pivoting operation of lever member 46 in the closing direction. Specifically, a pair of brackets 58 is provided integrally with each pivot shaft 44. In other words, two pairs of brackets 58 are integrally provided via the pair of pivot shafts 44 on the side of the base end of lever member 46, and the two pairs of brackets 58 are apart from each other in the front-back direction.

Pressing roller 60 that presses the side of the leading end of link member 48 is rotatably provided in each bracket 58. In other words, two pairs of pressing rollers 60 are rotatably provided via brackets 58 on the side of the base end of lever member 46, and the two pairs of pressing rollers 60 are apart from each other in the front-back direction. The rotational center of each pressing roller 60 is deviated from the pivot axis center of lever member 46 (the shaft center of pivot shaft 44). Each pressing roller 60 pivots integrally with lever member 46 about the pivot axis center of lever member 46.

As illustrated in FIGS. 9F to 9H, by interlocking pressing mechanism 56 by the pivoting operation of lever member 46 in the closing direction, locked portion 52 of each link member 48 pushes down cover member 32 toward the downward direction perpendicular to placement surface 26f of floating plate 26. In other words, by interlocking pressing mechanism 56 by the pivoting operation of lever member 46 in the closing direction, cover member 32 moves in the downward direction perpendicular to placement surface 26f of floating plate 26 via locked portion 52 of each link member 48.

A double lever that increases an operation force applied to lever member 46 and transmits the operation force from locked portion 52 of each link member 48 to cover member 32 is formed by each latch pin 40, lever member 46, each link member 48, and pressing mechanism 56. The double lever is a lever, in which pivot shaft 44 is used as a fulcrum, the side of the leading end of lever member 46 is used as an action point, and a pressing portion of pressing roller 60 is used as a force point, and a lever, in which pivot pin 50 is used as a fulcrum, the pressing portion of pressing roller 60 is used as an action point, and locked portion 52 is used as a force point. The double lever is a second-class lever.

As illustrated in FIG. 9H, when lever member 46 is closed, a force in the closing direction acts on lever member 46 from each pressing roller 60 by the biasing force of each spring 54. Thus, the closed state of lever member 46 can be stably maintained.

As illustrated in FIGS. 7, 8, and 10A to 10E, electrical component socket 10 includes cam mechanism 62 as a second interlocking mechanism that moves the two pairs of movable support members 28 in the downward direction in conjunction with the pivoting operation of lever member 46 in the closing direction. Specifically, each movable support member 28 is provided with cam guide 64 having a hole shape. A pair of cams 66 engaged with corresponding cam guide 64 is provided integrally with each pivot shaft 44. In other words, two pairs of cams 66 are integrally provided on the side of the base end of lever member 46 via the pair of pivot shafts 44, and the two pairs of cams 66 are apart from each other in the front-back direction. Each cam 66 pivots integrally with lever member 46 about the pivot axis center of lever member 46.

As illustrated in FIGS. 10A to 10E, by interlocking cam mechanism 62 by the pivoting operation of lever member 46 in the closing direction, support portion 30 of each movable support member 28 pushes down cover member 32 toward the downward direction perpendicular to placement surface 26f of floating plate 26. In other words, by interlocking cam mechanism 62 by the pivoting operation of lever member 46 in the closing direction, cover member 32 moves in the downward direction perpendicular to placement surface 26f of floating plate 26 via support portion 30 of each movable support member 28.

Here, the moving amount of support portion 30 of each movable support member 28 in the downward direction corresponds to the change amount of the distance from pivot shaft 44 to a pressing portion of cam 66 (a portion in contact with cam guide 64). In other words, pushing-down amount a of cover member 32 by support portion 30 of each movable support member 28 changes from d1 to d4 according to the change amount of the distance from pivot shaft 44 to the pressing portion of cam 66. In addition, after cover member 32 is switched to the horizontally fallen posture, the pushing-down amount of cover member 32 by support portion 30 of each movable support member 28 is identical to the pushing-down amount of cover member 32 by locked portion 52 of each link member 48. For example, when pushing-down amount a of cover member 32 by support portion 30 of each movable support member 28 is d1, d2, and d3, the pushing-down amount of cover member 32 by locked portion 52 of each link member 48 is also d1, d2, and d3, respectively.

A lever that increases the operation force applied to lever member 46 and transmits the operation force from support portion 30 of each movable support member 28 to cover member 32 is formed by lever member 46 and cam mechanism 62. The lever is a lever, in which pivot shaft 44 is used as a fulcrum, the side of the leading end of lever member 46 is used as an action point, and the pressing portion of cam 66 (the portion in contact with cam guide 64) is used as a force point, and is a second-class lever.

As illustrated in FIGS. 9H and 10E, after cover member 32 is switched to the horizontally fallen posture, the position of locked portion 52 of each link member 48 and the position of support portion 30 of each movable support member 28 are asymmetric with respect to the central position of cover member 32 in the longitudinal direction. The distance between the position of locked portion 52 of each link member 48 and the central position of cover member 32 in the longitudinal direction is shorter than the distance between the position of support portion 30 of each movable support member 28 and the central position of cover member 32 in the longitudinal direction. The magnification of the increase in the operation force by the double lever is smaller than the magnification of the increase in the operation force by the lever. Thus, the operation force applied to lever member 46 can be efficiently transmitted to cover member 32.

Subsequently, a usage operation of electrical component socket 10 according to the present embodiment will be described.

As illustrated in FIG. 1, electrical component P is accommodated in floating plate 26 as the accommodation portion of socket main body 12. Next, as illustrated in FIGS. 9A to 9F, cover member 32 is switched from the erected posture to the horizontally fallen posture by the pivoting operation of cover member 32 in the closing direction. During (immediately before) the switching of cover member 32 to the horizontally fallen posture, each latch pin 40 climbs over each locked portion 52 against the biasing force of spring 54 and is then locked to each locked portion 52 by the biasing force of spring 54.

Thereafter, as illustrated in FIGS. 9F to 9H, by interlocking pressing mechanism 56 by the pivoting operation of lever member 46 in the closing direction, locked portion 52 of each link member 48 pushes down cover member 32 toward the downward direction. In addition, as illustrated in FIGS. 10A to 10E, by interlocking cam mechanism 62 by the pivoting operation of lever member 46 in the closing direction, support portion 30 of each movable support member 28 pushes down cover member 32, whose posture is the horizontally fallen posture, toward the downward direction. Thus, pressing member 36 of cover member 32 presses electrical component P accommodated in socket main body 12, and each terminal of electrical component P and each electrode of the test wiring board can be electrically connected to each other via each contact pin of contact pin unit 20. As a result, an electrical test such as a bar-in test of electrical component P can be conducted by a test apparatus.

According to the configuration of electrical component socket 10 according to the present embodiment, as described above, each latch pin 40 as a part of cover member 32 is locked to each locked portion 52 by the pivoting operation of cover member 32 in the closing direction. In addition, by interlocking pressing mechanism 56 with cam mechanism 62 by the pivoting operation of lever member 46 in the closing direction, locked portion 52 of each link member 48 and support portion 30 of each movable support member 28 push down cover member 32 toward the downward direction. For this reason, when cover member 32 presses electrical component P, a force in the downward direction, instead of the oblique downward direction, acts on electrical component P from cover member 32. As a result, it is possible to avoid lateral displacement of electrical component P on socket main body 12 or rubbing by cover member 32 against the upper surface of electrical component P.

Accordingly, electrical component socket 10 according to the present embodiment makes it possible to suppress damage to a terminal of electrical component P and the occurrence of a scratch on the upper surface of electrical component P when an electrical test of electrical component P is conducted.

In addition, according to the configuration of electrical component socket 10 according to the present embodiment, as described above, locked portion 52 of each link member 48 and support portion 30 of each movable support member 28 push down cover member 32 toward the downward direction by the pivoting operation of lever member 46 in the closing direction. For this reason, cover member 32 in the horizontally fallen posture can be stably moved in the downward direction only by performing the pivoting operation of one lever member 46.

Accordingly, electrical component socket 10 according to the present embodiment makes it possible to improve the operability (handleability) of electrical component socket 10.

In addition, as described above, after cover member 32 is switched to the horizontally fallen posture, the pushing-down amount of cover member 32 by support portion 30 of each movable support member 28 is identical to the pushing-down amount of cover member 32 by locked portion 52 of each link member 48. For this reason, cover member 32 in the horizontally fallen posture can be moved more stably in the downward direction.

Accordingly, electrical component socket 10 according to the present embodiment makes it possible to further improve the operability of electrical component socket 10.

In addition, according to the configuration of electrical component socket 10 according to the present embodiment, as described above, each latch pin 40 as a part of cover member 32 is locked to each locked portion 52 by the pivoting operation of cover member 32 in the closing direction. In addition, pressing roller 60 that presses the side of the leading end of link member 48 is rotatably provided on the side of the base end of lever member 46, and the rotational center of pressing roller 60 is deviated from the pivot axis center of lever member 46. For this reason, even when the operation force of lever member 46 is small, a force in the downward direction (pushing-down force) with a sufficient magnitude can be generated at locked portion 52 of link member 48 by using the double lever described above. In particular, in a case where each locked portion 52 is located at a position closer to the base end of each link member 48 than to the leading end of each link member 48, the effect of the lever using locked portion 52 as a force point can be sufficiently exhibited.

Accordingly, electrical component socket 10 according to the present embodiment makes it possible to further improve the operability of electrical component socket 10.

In addition, according to the configuration of electrical component socket 10 according to the present embodiment, as described above, cam guide 64 is provided in each movable support member 28, and cam 66 engaged with cam guide 64 is integrally provided on the side of the base end of lever member 46. For this reason, even when the operation force of lever member 46 is small, a force in the downward direction (pushing-down force) with a sufficient magnitude can be generated at support portion 30 of movable support member 28 by using the lever.

Accordingly, electrical component socket 10 according to the present embodiment makes it possible to further improve the operability of electrical component socket 10.

The present embodiment has been specifically described above, but the present invention is not limited to the above-described specific embodiment. Various modifications and changes can be made to the specific examples described in the above embodiment within the scope of the gist of the present invention described in the claims.

1. An electrical component socket, comprising:
a socket main body that accommodates an electrical component;
a movable support member that is provided on a side of one end of the socket main body so as to be movable in an up-down direction and includes a support portion;
a cover member of which a side of a base end is pivotably coupled to the support portion and which presses the electrical component accommodated in the socket main body;
a lever member of which a side of a base end is pivotably coupled to the side of the one end of the socket main body;
a link member of which a side of a base end is pivotably coupled to a side of another end of the socket main body and which includes a locked portion;
a first interlocking mechanism that presses a side of a leading end of the link member in a downward direction in conjunction with a pivoting operation of the lever member in a closing direction; and
a second interlocking mechanism that moves the movable support member in the downward direction in conjunction with the pivoting operation of the lever member in the closing direction, wherein
a part of the cover member is locked to the locked portion by a pivoting operation of the cover member in the closing direction, and
the locked portion and the support portion push down the cover member by interlocking the first interlocking mechanism with the second interlocking mechanism by the pivoting operation of the lever member in the closing direction.

2. The electrical component socket according to claim 1, wherein:
the cover member is configured to switch between an erected posture and a horizontally fallen posture by the pivoting operation of the cover member, and
after the cover member is switched to the horizontally fallen posture, a pushing-down amount of the cover member by the support portion is identical to a pushing-down amount of the cover member by the locked portion.

3. The electrical component socket according to claim 1, wherein:
the cover member includes:
a cover member main body of which a side of a base end is pivotably coupled to the support portion;
a latch member that is provided on a side of a leading end of the cover member main body so as to be movable in a longitudinal direction of the cover member main body and includes a latch pin; and
a latch biasing portion that biases the latch member in a direction of the leading end of the cover member main body, and
the latch pin as the part of the cover member is locked to the locked portion by the pivoting operation of the cover member in the closing direction.

4. The electrical component socket according to claim 3, wherein
the latch pin climbs over the locked portion against a biasing force of the latch biasing portion by the pivoting operation of the cover member in the closing direction, and is then locked to the locked portion by the biasing force of the latch biasing portion.

5. The electrical component socket according to claim 1, wherein
the first interlocking mechanism includes a pressing roller, wherein the pressing roller is rotatably provided on the side of the base end of the lever member, has a rotational center deviated from a pivot axis center of the lever member, and presses the side of the leading end of the link member.

6. The electrical component socket according to claim 5, further comprising a link biasing portion that biases the link member in an opening direction, wherein
when the lever member is closed, a force in the closing direction acts on the lever member from the pressing roller by a biasing force of the link biasing portion.

7. The electrical component socket according to claim 1, wherein
the second interlocking mechanism includes:
a cam guide that is provided in the movable support member; and
a cam that is provided on the side of the base end of the lever member and is engaged with the cam guide.

8. The electrical component socket according to claim 1, wherein
the locked portion is located at a position closer to the base end of the link member than to the leading end of the link member.

9. The electrical component socket according to claim 2, wherein:
a double lever that increases an operation force applied to the lever member and transmits the operation force to the cover member is formed by the part of the cover member, the lever member, the link member, and the first interlocking mechanism, and
a lever that increases the operation force applied to the lever member and transmits the operation force to the cover member is formed by the lever member and the second interlocking mechanism.

10. The electrical component socket according to claim 9, wherein:
after the cover member is switched to the horizontally fallen posture, a position of the locked portion and a position of the support portion are asymmetric with respect to a central position of the cover member in a longitudinal direction, and
after the cover member is switched to the horizontally fallen posture, a magnification of an increase in the operation force by the double lever and a magnification of an increase in the operation force by the lever are different from each other.

11. The electrical component socket according to claim 10, wherein:
after the cover member is switched to the horizontally fallen posture, a distance between the position of the locked portion and the central position of the cover member in the longitudinal direction is shorter than a distance between the position of the support portion and the central position of the cover member in the longitudinal direction, and
after the cover member is switched to the horizontally fallen posture, the magnification of the increase in the operation force by the double lever is smaller than the magnification of the increase in the operation force by the lever.
